(19) United States
(12) Patent Application Publication
(10) Pub. No.: US 2026/0195507 A1
(43) Pub. Date: Jul. 9, 2026

(54) ACCELERATED MULTIPHYSICS ASSESSMENT FOR AIRBAG DESIGN

(71) Applicant: Siemens Industry Software NV, Leuven (BE)

(72) Inventors: Jose Valenzuela Del Rio, Orlando, FL (US); Lucia Mirabella, Plainsboro, NJ (US); Emmanuel Motheau, Pennington, NJ (US); Elena Arvanitis, Somerville, NJ (US); Richard Lancashire, Leiden (NL); Karan Chatrath, Rijswijk, South Holland (NL); Peter Ritmeijer, Delft (NL)

(73) Assignee: Siemens Industry Software NV, Leuven (BE)

(21) Appl. No.: 19/128,282

(22) PCT Filed: Aug. 17, 2023
(86) PCT No.: PCT/US2023/030478

§ 371 Date: May 8, 2025

Related U.S. Application Data
(60) Provisional application No. 63/383,536, filed on Nov. 14, 2022.

(51) Int. Cl. G06F 30/27; B60R 21/16

(52) U.S. Cl. CPC G06F 30/27; B60R 21/16

(57) ABSTRACT

A method for modeling airbag designs includes training a reduced order parametric model (104) of an airbag system for evaluating different airbag designs. Training the model includes applying a high-order multi-physics model (102) to an airbag system in the design space to produce snapshots (103) of performance over time. A reduced order model (104) constructs reduced bases (105) from the high-order snapshots (103) and a set of modal coefficients (107) are projected. A fit regression model (108) produces the parametric model (109). The parametric model is built and trained in an offline process, while the evaluating of an airbag design is done online. The reduced order model may be created using proper orthogonal decomposition a greedy algorithm and the regression model may be implemented in a machine learning model or in a Gaussian Process. Evaluating an airbag design uses parameters describing an airbag, or an environment where the airbag operates to the parametric model.

### TECHNICAL FIELD

This application relates to the design of manufactured objects.

### BACKGROUND

In the design of some objects such as automotive airbags, reliable simulation of airbag inflation requires the combination of multiple physics such as large displacement structural dynamics, fluid dynamics and multi-body dynamics. Numerical methods exist to simulate each of these physics. Finite Element methods are widely used for structures including scenarios with large deformations as required for airbag inflation. Fluid dynamics problems are commonly tackled by Computational Fluid Dynamics (CFD) which has successfully been proven in multiple applications including the gas filling of containers. In the multi-body simulation arena, time-marching schemes such as modified Euler and Runge-Kutta are commonly used to assess the solutions. However, complexity rises considerably when considering the interactions between the airbag and dynamic physical environment, and due to the required number of physics and their coupling that result in very large simulation times for analyzing the inflation of a given airbag in a given car and for a given passenger. Possible dynamic physical environments include but are not limited to car interiors, car belted passengers, pedestrians or cyclists with protection systems on a road, by way of non-limiting example.

### SUMMARY

According to embodiments described in this disclosure, a method for modeling airbag designs includes for a given airbag design, applying a high-order multi-physics model to produce snapshots of the airbag performance over time. Then, in a reduced order model constructing airbag bases from the high-order snapshots, projecting the reduced order output and the snapshots to produce a set of modal coefficients for the airbag bases. A fit regression model is evaluated to produce a parametric model of the airbag. An airbag design is then evaluated using the parametric model saving time and allowing for more designs to be evaluated. The parametric model of the airbag is built and trained in an offline process, while the evaluation of an airbag design in the parametric model is done in an online process. In the airbag design process, a design decision is made based on the results of the evaluation. The reduced order model may be created using proper orthogonal decomposition, a greedy algorithm, or non-linear manifold learning by way of non-limiting example. The regression model may be implemented in a machine learning model or in a Gaussian Process by way of non-limiting example. Evaluating an airbag design may be performed by inputting parameters describing one of a plurality of airbags to the parametric model. According to some embodiments evaluating an airbag design may be performed by inputting parameters describing an environment where the airbag operates to the parametric model. The airbag design used to train a parametric model comprises an airbag system selected from a target design space. Evaluation of an airbag system using the parametric model includes generating a full order response in the parametric space using back projection.

A system for modeling airbag designs comprising a computer processor, and a non-transitory computer memory in communication with the computer processor, the non-transitory computer memory storing instructions that when executed by the computer processor, cause the computer processor to perform the steps of for a given airbag design, applying a high-order multi-physics model to produce snapshots of the airbag performance over time in a reduced order model, constructing airbag bases from the high-order snapshots, projecting the snapshots over reduced order bases to produce a set of modal coefficients for the airbag bases; performing a fit regression model to produce a parametric model of the reduced order coefficients of the airbag; and evaluating an airbag design using the parametric model and reduced order bases. Producing of the parametric model of the airbag may be performed offline. Evaluating of an airbag design may be done in an online process. Based on the results of the evaluation using the parametric model, a design alternative may be selected. Reduced order modelling may be performed using proper orthogonal decomposition., by using a greedy algorithm, or non-linear manifold learning. The regression modelling may include a machine learning model or a Gaussian Process by way of example.

### BRIEF DESCRIPTION OF THE DRAWINGS

The foregoing and other aspects of the present invention are best understood from the following detailed description when read in connection with the accompanying drawings. For the purpose of illustrating the invention, there is shown in the drawings embodiments that are presently preferred, it being understood, however, that the invention is not limited to the specific instrumentalities disclosed. Included in the drawings are the following Figures:

FIG. 1 is a block diagram of an offline training process for creating a parametric model from a reduced order model according to aspects of embodiment of this disclosure.

FIG. 2 is an illustration of the online evaluation of a reduced order parametric model according to aspects of embodiments of this disclosure.

FIG. 3 is a block diagram of a computer system, which may be used for implementing a reduced order parametric model for design according to aspects of embodiments of this disclosure.

### DETAILED DESCRIPTION

The complexity involving multi-physics airbag inflation simulations results in a very time-consuming airbag design process. For example, many airbag variations must be analyzed and simulated to obtain the most appropriate airbag given the design requirements. Similarly, automotive design involves airbag selection and placement, which is also a time-consuming process for similar reasoning. The computational demands of such simulations limit the design space exploration that can be explored leading to fewer and less robust designs than might otherwise be possible in the time allowed.

The current computationally expensive approaches to solve airbag inflation hinder product quality and extend time-to-market for several automotive and/or aerospace stakeholders such as airbag designers, mobility original equipment manufacturers (OEM) designers and testers, among others. Embodiments described in this disclosure aim to provide airbag simulation techniques that reduce time-to-market and increase product quality and robustness for airbag and mobility OEM designers.

The present state-of-the-art approach to simulating airbag gas inflation is to couple solvers of the multiple physics involved. Physics are simulated separately for certain time spans and coupled together at given times to share information and boundary conditions such that they converge and are consistent. Depending on the frequency of coupling multi-physics, solvers are called either loosely coupled or tightly coupled. The former solvers are coupled and communicate with each other less frequently than the latter.

One conventional solution for airbag design allows a designer to model and simulate restraint systems such as airbags, belts, passengers, and other car crash-relevant components in the interior of a car. This solution includes multi-body, finite element analysis (FEA) and computational fluid dynamics (CFD) into a solver that balances solver speed with modelling detail. However, simulation times still hinder the airbag and car time-to-market as many simulations need to be run when designers assess robustness of design changes or optimalizations. This results in large design times despite the state-of-the-art solution balance between speed and detail. Based on the multi-body approach, these solvers are considerably faster than most FEA solutions alone. However, depending on the airbag design cases and when considering a finite element (FE) airbag with a CFD interaction, computation times are slowed down considerably, resulting in a decrease or loss of the time advantage. Therefore, an alternative method, such as Deep Neural Networks (DNNs), that may offer sufficient accuracy and robustness while preserving or increasing time advantage, is of prime importance to maintain competitive advantage.

Active research focuses on solver coupling acceleration, which is intrusive (requiring source code access and even source code modification). These solutions have a limited simulation time reduction since high-fidelity and high-order solvers are still used for each of the relevant physics. Additionally, they are not easy to use because these multi-physics codes are complex and often convoluted.

Embodiments of this disclosure present a non-intrusive workflow combining model order reduction and machine learning (ML) to create a parametric model that accelerates the simulation of the dynamic multi-physics airbag inflation against the dynamic physical environment (e.g., passenger, car/train/aircraft interior, belt, cyclist, etc.). The parametric feature of the model allows the ML-model to assess several airbags and/or variations of interactions with people and the physical environment, resulting in fast simulations throughout the design space defined by these model parameters.

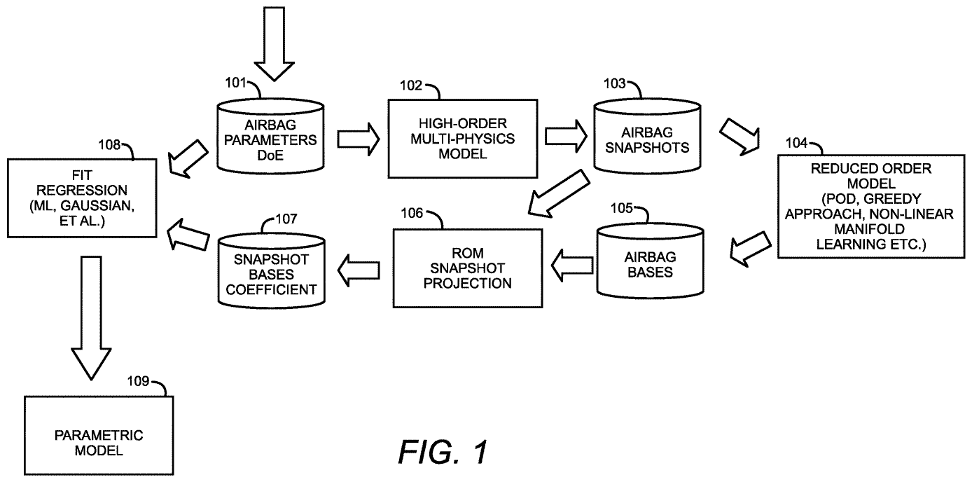

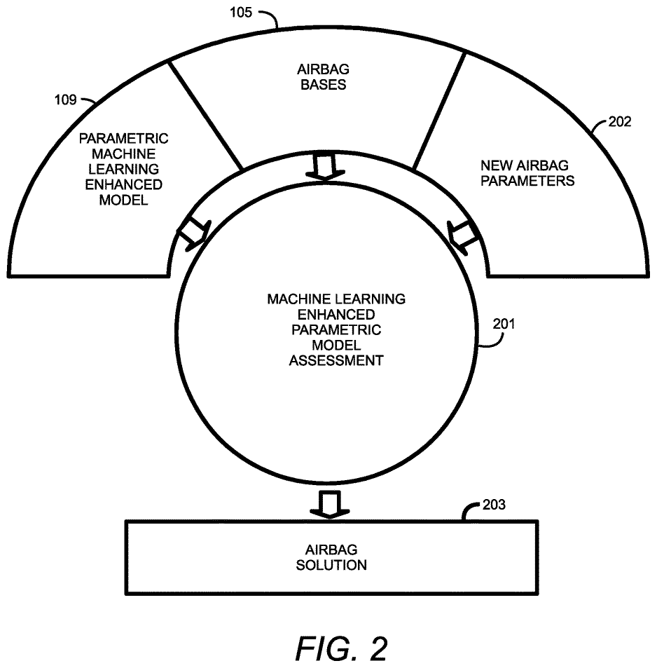

The presented workflow involves two parts: an offline process where the model is trained and built shown in FIG. 1 and an online process where the trained model is used to evaluate and design airbags and/or inflation against several object or agents in their embedding physical environment as depicted in FIG. 2. During the training phase, multiple airbag systems in a desired parameter space 101 are evaluated with a state-of-the-art multi-physics evaluator 102. The results or snapshots 103 are employed to assess system modes or bases 105 via any relevant reduce order method 104 including but not limited to proper orthogonal decomposition (POD), greedy algorithms or manifold learning. Once the modes 105 are available, the modal coefficients 107 for the training snapshots are obtained by snapshot projection 106 onto the modes 105. Finally, a regressor 108 that maps airbag system parameters and time to modes coefficient is constructed. The potential regressors 108 include but are not limited to neural networks, Gaussian processes, or response surfaces.

During the online phase, designers or optimization engineers assess airbag system performance in the parametric model by evaluating the reduced order model 109 and subsequently obtaining the full order response by a computationally inexpensive back projection step. These online evaluations are much faster than the state-of-the-art multi-physics-based simulation because of their computational simplicity, mode expansion and regressor inference.

An important development of the described embodiments is the time for system evaluation, which is much shorter than conventional techniques. Because of the ML-enhanced model reduced complexity, airbag system evaluations are much shorter and may be up to four orders of magnitude faster. For example, a conventional solution may take 2500 seconds to perform airbag simulation using a multi-physics solver as compared to embodiments described herein that require only 0.2 seconds using a reduced order parametric model simulation both using the same computational hardware.

Additionally, the parametric nature of this solution allows the ML-enhanced models to be valid on wide design spaces of airbag systems. That is, the same ML-enhanced models may be used to evaluate multiple airbag systems within the design space defined by the training snapshots.

Combining the time advantage together with the parametric nature of the model translates into faster design, optimization, and robustness checks. Therefore, time-to-market is reduced, and better more robust system performance is achieved for airbag and car designers. Furthermore, the ML-enhanced solution is nonintrusive due to the estimation of the modes and their coefficients being done through model order reduction and regression. It should be noted that neither of these techniques requires a change to the underlying airbag inflation simulation code.

FIG. 2 shows the online process for evaluating an airbag and its environment in a reduced order parametric model according to embodiments of the disclosure. The machine learning enhanced parametric model 109 is fed by the parameters of the airbag being evaluated 202 to produce the Snapshot Bases Coefficients, which together with the airbag bases 105 leads to the Airbag Solution 203. The airbag parameters may represent properties of the airbag itself or may include values that are representative of objects in the environment in which the airbag operates. The machine learning enhanced parametric model 109 together with the Airbag Bases 105 performs the assessment 201 to produce an airbag solution 203. Due to the computational simplicity of the parametric model 109, a designer may perform more evaluations for a given time budget than conventional solutions relying on physics solvers. This allows a more comprehensive exploration of the design space to ensure better solutions in less time, thereby improving outcomes, while reducing time-to-market for higher quality products.

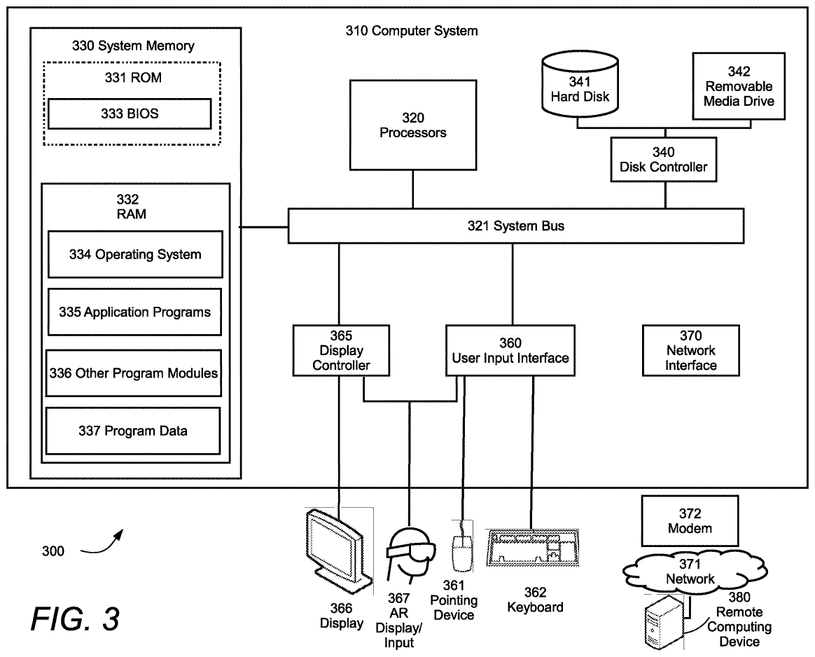

FIG. 3 illustrates an exemplary computing environment 300 within which embodiments of the invention may be implemented. Computers and computing environments, such as computer system 310 and computing environment 300, are known to those of skill in the art and thus are described briefly here.

As shown in FIG. 3, the computer system 310 may include a communication mechanism such as a system bus 321 or other communication mechanism for communicating information within the computer system 310. The computer system 310 further includes one or more processors 320 coupled with the system bus 321 for processing the information.

The processors 320 may include one or more central processing units (CPUs), graphical processing units (GPUs), or any other processor known in the art. More generally, a processor as used herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting or transmitting information for use by an executable procedure or an information device, and/or by routing the information to an output device. A processor may use or comprise the capabilities of a computer, controller or microprocessor, for example, and be conditioned using executable instructions to perform special purpose functions not performed by a general-purpose computer. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device.

Continuing with reference to FIG. 3, the computer system 310 also includes a system memory 330 coupled to the system bus 321 for storing information and instructions to be executed by processors 320. The system memory 330 may include computer readable storage media in the form of volatile and/or nonvolatile memory, such as read only memory (ROM) 331 and/or random-access memory (RAM) 332. The RAM 332 may include other dynamic storage device(s) (e.g., dynamic RAM, static RAM, and synchronous DRAM). The ROM 331 may include other static storage device(s) (e.g., programmable ROM, erasable PROM, and electrically erasable PROM). In addition, the system memory 330 may be used for storing temporary variables or other intermediate information during the execution of instructions by the processors 320. A basic input/output system 333 (BIOS) containing the basic routines that help to transfer information between elements within computer system 310, such as during start-up, may be stored in the ROM 331. RAM 332 may contain data and/or program modules that are immediately accessible to and/or presently being operated on by the processors 320. System memory 330 may additionally include, for example, operating system 334, application programs 335, other program modules 336 and program data 337.

The computer system 310 also includes a disk controller 340 coupled to the system bus 321 to control one or more storage devices for storing information and instructions, such as a magnetic hard disk 341 and a removable media drive 342 (e.g., floppy disk drive, compact disc drive, tape drive, and/or solid-state drive). Storage devices may be added to the computer system 310 using an appropriate device interface (e.g., a small computer system interface (SCSI), integrated device electronics (IDE), Universal Serial Bus (USB), or FireWire).

The computer system 310 may also include a display controller 365 coupled to the system bus 321 to control a display or monitor 366, such as a cathode ray tube (CRT) or liquid crystal display (LCD), for displaying information to a computer user. The computer system includes an input interface 360 and one or more input devices, such as a keyboard 362 and a pointing device 361, for interacting with a computer user and providing information to the processors 320. The pointing device 361, for example, may be a mouse, a light pen, a trackball, or a pointing stick for communicating direction information and command selections to the processors 320 and for controlling cursor movement on the display 366. The display 366 may provide a touch screen interface which allows input to supplement or replace the communication of direction information and command selections by the pointing device 361. In some embodiments, an augmented reality device 367 that is wearable by a user, may provide input/output functionality allowing a user to interact with both a physical and virtual world. The augmented reality device 367 is in communication with the display controller 365 and the user input interface 360 allowing a user to interact with virtual items generated in the augmented reality device 367 by the display controller 365. The user may also provide gestures that are detected by the augmented reality device 367 and transmitted to the user input interface 360 as input signals.

The computer system 310 may perform a portion or all of the processing steps of embodiments of the invention in response to the processors 320 executing one or more sequences of one or more instructions contained in a memory, such as the system memory 330. Such instructions may be read into the system memory 330 from another computer readable medium, such as a magnetic hard disk 341 or a removable media drive 342. The magnetic hard disk 341 may contain one or more datastores and data files used by embodiments of the present invention. Datastore contents and data files may be encrypted to improve security. The processors 320 may also be employed in a multi-processing arrangement to execute the one or more sequences of instructions contained in system memory 330. In alternative embodiments, hard-wired circuitry may be used in place of or in combination with software instructions. Thus, embodiments are not limited to any specific combination of hardware circuitry and software.

As stated above, the computer system 310 may include at least one computer readable medium or memory for holding instructions programmed according to embodiments of the invention and for containing data structures, tables, records, or other data described herein. The term “computer readable medium” as used herein refers to any medium that participates in providing instructions to the processors 320 for execution. A computer readable medium may take many forms including, but not limited to, non-transitory, non-volatile media, volatile media, and transmission media. Non-limiting examples of non-volatile media include optical disks, solid state drives, magnetic disks, and magneto-optical disks, such as magnetic hard disk 341 or removable media drive 342. Non-limiting examples of volatile media include dynamic memory, such as system memory 330. Non-limiting examples of transmission media include coaxial cables, copper wire, and fiber optics, including the wires that make up the system bus 321. Transmission media may also take the form of acoustic or light waves, such as those generated during radio wave and infrared data communications.

The computing environment 300 may further include the computer system 310 operating in a networked environment using logical connections to one or more remote computers, such as remote computing device 380. Remote computing device 380 may be a personal computer (laptop or desktop), a mobile device, a server, a router, a network PC, a peer device or other common network node, and typically includes many or all of the elements described above relative to computer system 310. When used in a networking environment, computer system 310 may include modem 372 for establishing communications over a network 371, such as the Internet. Modem 372 may be connected to system bus 321 via user network interface 370, or via another appropriate mechanism.

Network 371 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 310 and other computers (e.g., remote computing device 380). The network 371 may be wired, wireless or a combination thereof. Wired connections may be implemented using Ethernet, Universal Serial Bus (USB), RJ-6, or any other wired connection generally known in the art. Wireless connections may be implemented using Wi-Fi, WiMAX, and Bluetooth, infrared, cellular networks, satellite or any other wireless connection methodology generally known in the art. Additionally, several networks may work alone or in communication with each other to facilitate communication in the network 371.

An executable application, as used herein, comprises code or machine-readable instructions for conditioning the processor to implement predetermined functions, such as those of an operating system, a context data acquisition system or other information processing system, for example, in response to user command or input. An executable procedure is a segment of code or machine-readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters.

A graphical user interface (GUI), as used herein, comprises one or more display images, generated by a display processor and enabling user interaction with a processor or other device and associated data acquisition and processing functions. The GUI also includes an executable procedure or executable application. The executable procedure or executable application conditions the display processor to generate signals representing the GUI display images. These signals are supplied to a display device which displays the image for viewing by the user. The processor, under control of an executable procedure or executable application, manipulates the GUI display images in response to signals received from the input devices. In this way, the user may interact with the display image using the input devices, enabling user interaction with the processor or other device.

The functions and process steps herein may be performed automatically or wholly or partially in response to user command. An activity (including a step) performed automatically is performed in response to one or more executable instructions or device operation without user direct initiation of the activity.

The system and processes of the figures are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. As described herein, the various systems, subsystems, agents, managers and processes can be implemented using hardware components, software components, and/or combinations thereof.

1. A method for multi-physics modeling of airbag designs comprising:
for a given airbag design and the environment where the airbag operates, applying a high-order multi-physics model to produce snapshots of the airbag performance over time;
in a reduced order model, constructing airbag reduced bases from the high-order multi-physics snapshots;
projecting the snapshots onto the airbag reduced bases to produce a set of modal coefficients for the airbag bases;
performing a fit regression model to produce a parametric model of the airbag; and
evaluating an airbag design using the parametric model.

2. The method of claim 1, wherein the producing of the parametric model of the airbag is performed offline.

3. The method of claim 1, wherein the evaluating of an airbag design is done in an online process.

4. The method of claim 1, further comprising:
performing a design decision based on the results of the evaluation using the parametric model.

5. The method of claim 1, wherein the reduced order model is performed using proper orthogonal decomposition.

6. The method of claim 1, wherein the reduced order model is performed using a greedy algorithm.

7. The method of claim 1, wherein the reduced order model is performed using non-linear manifold learning.

8. The method of claim 1, wherein the regression model comprises a machine learning model.

9. The method of claim 1, wherein the regression model is a Gaussian Process.

10. The method of claim 1, wherein evaluating an airbag design comprises:
inputting parameters describing one of a plurality of airbags to the parametric model.

11. The method of claim 1, wherein evaluating an airbag design comprises:
inputting parameters describing an environment where the airbag operates to the parametric model.

12. The method of claim 1, wherein the airbag design comprises an airbag system selected from a target design space.

13. The method of claim 1, further comprising:
generating a full order response in the parametric using back projection.

14. A system for modeling airbag designs comprising:
a computer processor; and
a non-transitory computer memory in communication with the computer processor, the non-transitory computer memory storing instructions that when executed by the computer processor, cause the computer processor to perform the steps of:
for each airbag design and environment where the airbag operates in the training set, applying a high-order multi-physics model to produce snapshots of the airbag performance over time;
in a reduced order model, constructing airbag reduced bases from the high-order snapshots;
projecting the snapshots onto the airbag reduced bases to produce a set of modal coefficients for the airbag bases;
performing a fit regression model to produce a parametric model of the airbag; and
for an unseen airbag design or environment where the airbag operates (not part of the training set), evaluating an airbag design using the parametric model.

15. The system of claim 14, wherein the producing of the parametric model of the airbag is performed offline.

16. The system of claim 14, wherein the evaluating of an airbag design is done in an online process.

17. The system of claim 14, the non-transitory computer memory further storing instructions that when executed by the computer processor, cause the computer processor to perform the steps of:
performing a design decision based on the results of the evaluation using the parametric model.

18. The system of claim 14, wherein the reduced order model is performed using proper orthogonal decomposition.

19. The system of claim 14, wherein the reduced order model is performed using a greedy algorithm.

20. The system of claim 14, wherein the reduced order model is performed using non-linear manifold learning.

21. (canceled)

22. (canceled)
